(19) United States
(12) Patent Application Publication
(10) Pub. No.: US 2009/0085605 A1
(43) Pub. Date: Apr. 2, 2009

(54) SYSTEM AND METHOD FOR PARALLEL BURNING USING MULTIPLEX TECHNOLOGY

(75) Inventors: Quan-Jie ZHENG, Tianjin (CN); Xue-Shan HAN, Tianjin (CN); Jeff SONG, Taipei (TW); Jhih-Ren JIN, Taipei (TW); Tom CHEN, Taipei (TW); Win-Harn LIU, Taipei (TW)

Correspondence Address: Workman Nydegger;1000 Eagle Gate Tower, 60 East South Temple, Salt Lake City, UT, 84111, US

(73) Assignee: INVENTEC CORPORATION, Taipei (TW)

(21) Appl. No.: 11/864,570

(22) Filed: Sep. 28, 2007

(51) Int. Cl. H03K 19/173

(52) U.S. Cl. 326/37

(57) ABSTRACT

A system and method for parallel burning using multiplex technology is used for burning chips of different bus types on the same transmission bus at the same time in parallel. A main control unit divides bandwidth of the transmission bus into different frequency bands, sends a control command including a command for sending data carrying bus signals of designated types, and controls data carrying the bus signals of the designated types to be transmitted in designated frequency bands of the transmission bus. Then, a sending unit sends the data carrying the bus signals of the designated types in the designated frequency band. Finally, receiving units receive the data transmitted in the designated frequency bands, and then output them to a plurality of burners such as to burn the data onto the chips of the designated bus types in parallel.

### BACKGROUND

1. Field of the Invention

The present invention relates to a system and a method for burning chip, and more particularly to a system and method for parallel burning using multiplex technology for burning the chips of different bus types on the same transmission bus at the same time in parallel using the multiplex technology.

2. Related Art

In the prior art, chip-burning systems mainly include serial burning systems and parallel burning systems. The serial burning systems can be further classified into one-to-one serial burning systems and one-to-many serial burning systems for chips of the same type. These burning systems are described below.

1. In one-to-one serial burning system, one controller burns the chips of a single type in a specific time period. However, one controller only serially burns the chips. If the chips need to be burned in parallel, a plurality of controllers is required to perform the burning in an equivalent superposition mode, so as to burn the chips in parallel.

2. In one-to-many serial burning system for the chips of the same type, one controller burns many chips of the same type one by one during a specific time period through switching electronic switches. Alternatively, the switches are switched during a bus waiting period according to characteristics of the bus, thereby achieving the one-to-many burning of the chips. However, one controller only burns the chips of the same bus type during the same time period. If the chips of different bus types need to be burned, many controllers are required to perform the burning in an equivalent superposition mode.

3. In parallel burning system with many controllers which control parallel burning operations of many chips, the chips can be of the same bus type or different bus types. However, when performing the burning operations of the chips in parallel, many controllers are required as well.

As known form the burning systems in the prior art, the conventional burning systems have the following problems.

One controller can only realize the burning operation of single chip or the burning operations of the chips of the same bus type. In order to burn the chips of different bus types, the controllers are required to operate at the same time. Therefore, when the chips of different bus types are burned with the conventional chip burning systems and methods, more time is consumed, and hardware resources are wasted.

### SUMMARY

In order to solve the problems and defects of the prior art, the present invention is directed to a system and method for parallel burning using multiplex technology, which are applicable for burning chips of different bus types on the same transmission bus at the same time in parallel.

The present invention provides a parallel burning system using multiplex technology, including a main control unit, a sending unit, receiving units and burners.

The main control unit can divide bandwidth of a transmission bus into different frequency bands, send a control command having a command for sending data carrying bus signals of designated types, and control the data carrying the bus signals of the designated types to be transmitted in designated frequency bands of the transmission bus. The sending unit can receive the command for sending the data carrying the bus signals of the designated types, and then send the data carrying the bus signals of the designated types in the designated frequency bands. Each receiving unit can receive the data transmitted in the designated frequency band, and transmit the data to the corresponding burner. Each burner can burn the data transmitted from the corresponding receiving unit to the chip of the designated bus type in parallel.

Each receiving unit can also receive feedback signal from the chip of the designated bus type to the sending unit, and then the sending unit can transmit the feedback signals of the chips to the main control unit.

Each of the receiving units further includes: a modulating unit, for modulating the feedback signal from the chip of the designated bus type into a signal with specific identification information of the chip; and a demodulating unit, for demodulating the data carrying the bus signals of the designated types into data which is identifiable while burning the chips.

The sending unit further includes: a modulating unit, for modulating the data carrying the bus signals of different designated types into data transmissive in the same frequency band or different frequency bands of the transmission bus at the same time; and a demodulating unit, for demodulating the feedback signals of the chips of the designated bus type transmitted from the receiving units into information identifiable by the main control unit. In an embodiment, a modulating process of Code Division Multiple Access (CDMA) technology is used to modulate the data carrying the bus signals of different designated types into data transmissive in the same frequency band of the transmission bus at the same time, and a modulating process of Frequency Division Multiple Access (FDMA) is used to modulate the data carrying the bus signals of the different designated types into data transmissive in different frequency bands of the transmission bus at the same time.

The present invention provides a method for parallel burning using multiplex technology, which includes the following steps.

Bandwidth of a transmission bus is divided into different frequency bands. The control terminal sends a control command to control data carrying bus signals of designated types to be transmitted in designated frequency band of the transmission bus. A burning terminal receives the data transmitted in the designated frequency bands, and burns the data to chips of the designated bus types in parallel.

Moreover, the method for parallel burning using multiplex technology further includes the following step.

The burning terminal receives feedback signals from the chips of the designated bus type, and transmits the feedback signals of the chips to the control terminal.

Moreover, the method for parallel burning using multiplex technology further includes the following steps.

The burning terminal modulates the received feedback signals of the chips of the designated bus type into signals with specific identification information of the chips; and the burning terminal demodulates the received data transmitted in the designated frequency band into data which is identifiable while burning the chips.

Moreover, the method for parallel burning using multiplex technology further includes the following steps.

The control terminal modulates the data carrying the bus signals of different designated types into data which is simultaneously transmissive in the same frequency band or different frequency bands of the transmission bus. In an embodiment, the modulating process of CDMA technology is used to modulate the data carrying the bus signals of different designated types into data simultaneously transmissive in the same frequency band of the transmission bus, and the modulating process of FDMA is used to modulate the data carrying the bus signals of the different designated types into data that is simultaneously transmissive in different frequency bands of the transmission bus. And, the control terminal demodulates the feedback signals of the chips of the designated bus type from the burning terminal into information identifiable by the control terminal.

In the system and the method for parallel burning using multiplex technology according according to the present invention, one control unit can control the burning operations of chips of different bus types in the same transmission bus at the same time, so as to burn the chips of different types in parallel rapidly while saving hardware resources, and thus saving the time for burning the chips of different types, and improving the flexibility of burning the chips of different types as well.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, which thus is not limitative of the present invention, and wherein:

FIG. 1 is a block diagram of a system for parallel burning using multiplex technology according to an embodiment of the present invention;

FIG. 2 is a flow chart of a method for parallel burning using multiplex technology according to an embodiment of the present invention; and

FIG. 3 is a schematic view of a transmission bus line with intrinsic bandwidth division according to the present invention.

### DETAILED DESCRIPTION

Preferred embodiments of the present invention are illustrated below with reference to the accompanying drawings.

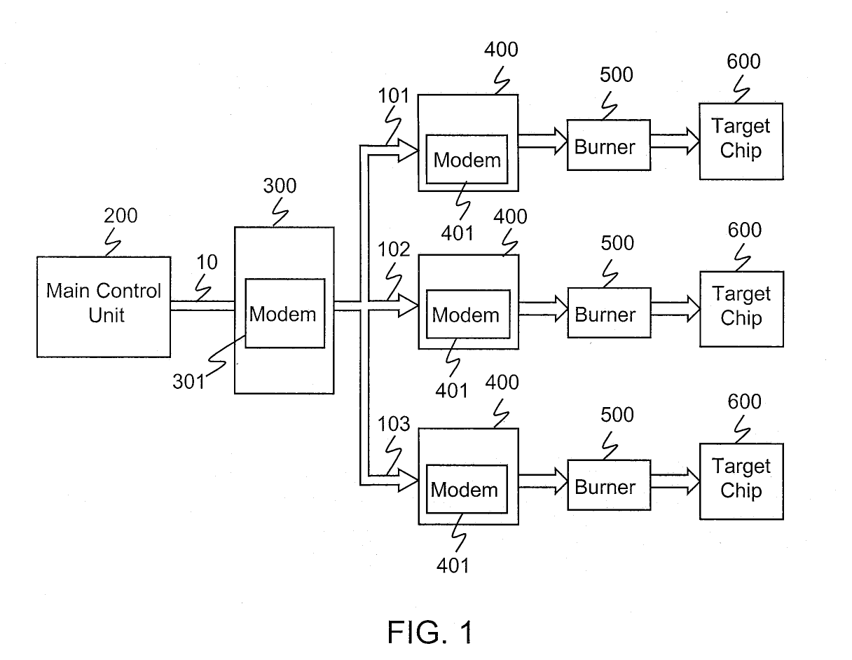

FIG. 1 is a block diagram of a system for parallel burning using multiplex technology according to an embodiment of the present invention. Referring to FIG. 1, the system for parallel burning using multiplex technology according to an embodiment of the present invention includes a main control unit 200, a sending unit 300, receiving units 400, and burners 500.

The main control unit 200 divides a bandwidth of a transmission bus 10 into different frequency bands 101, 102, and 103, sends a control command, and controls data carrying bus signals of designated types to be transmitted in the designated frequency bands 101, 102, and 103 of the transmission bus 10. The control command includes a command for sending the data carrying the bus signals of the designated types. The sending unit 300 receives the command for sending the data carrying the bus signals of designated types from the main control unit 200, and transmits the data carrying the bus signals of the designated types through the designated frequency bands 101, 102, and 103. The receiving units 400 receive the data transmitted from the sending unit 300, and transmit the data to the corresponding burners 500. The burners 500 burn the data from each of the receiving units 400 to target chips 600 of different bus types in parallel.

In addition, the receiving units 400 can also receive feedback signals from the target chips 600 of the different bus types after the burning is completed and transmit them back to the sending unit 300. Then, the sending unit 300 can transmit the feedback signals of the target chips 600 to the main control unit 200, so as to burn the target chips 600 of the different bus types in parallel.

The sending unit 300 and the receiving units 400 of the system for parallel burning using multiplex technology according to an embodiment of the present invention can include modems 301 and 401 respectively.

In the receiving units 400, the modems 401 are used to modulate the feedback signals from the target chips 600 of different bus types into signals with specific identification information (e.g., chip identification codes) of the target chips 600. In addition, the modems 401 are further used to demodulate the received modulated data carrying the bus signals of designated types into data identifiable while burning the target chips 600.

In the sending unit 300, the modem 301 is used to modulate data carrying the bus signals of different designated types into data transmissive in the same frequency band or different frequency bands of the transmission bus 10 at the same time. In this case, the modulating process of CDMA technology is used to modulate the data carrying the bus signals of different designated types into data transmissive in the same frequency band of the transmission bus 10 at the same time, and the modulating process of FDMA is used to modulate the data carrying the bus signals of different designated types into data transmissive in the different frequency bands of the transmission bus 10 at the same time. Moreover, the modem 301 is further used to demodulate the modulated feedback signals of the target chips 600 of the designated bus types from the receiving units 400 into information identifiable for the main control unit 200.

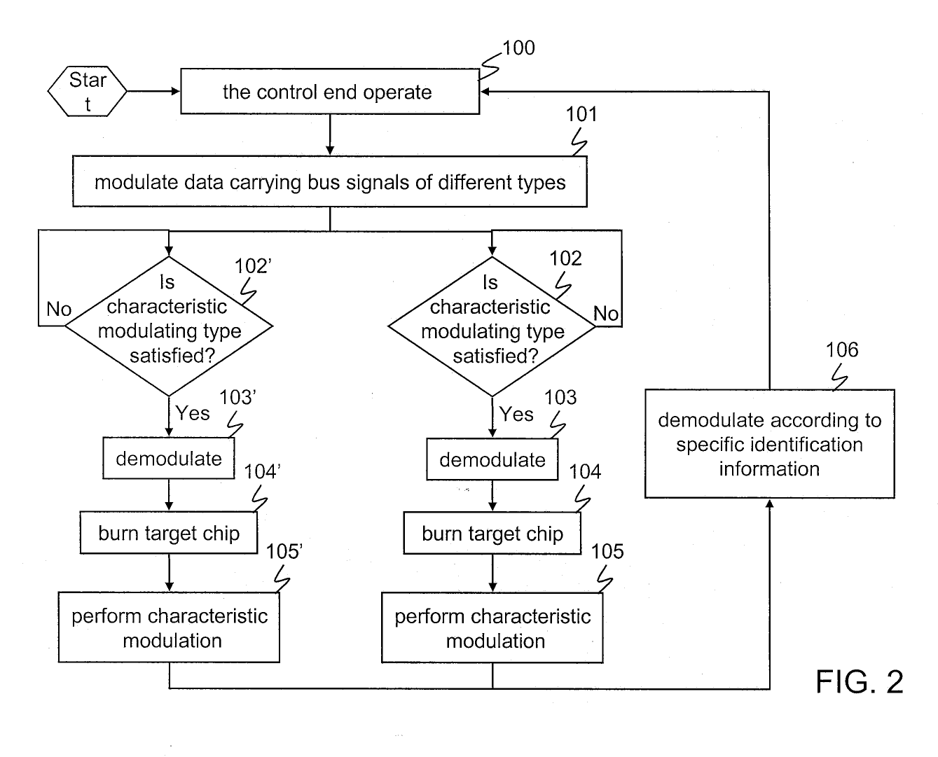

FIG. 2 is a flow chart of a method for parallel burning using multiplex technology according to an embodiment of the present invention. As shown in FIG. 2, the method for parallel burning using multiplex technology according to an embodiment of the present invention includes the following steps.

The control terminal is started and begins to operate (Step 100), wherein the control terminal divides a bandwidth of a transmission bus into different frequency bands, and sends a control command and data carrying bus signals of designated types. The control command can have a command for sending the data carrying the bus signals of designated types.

The control terminal modulates the data carrying the bus signals of different designated types into data transmissive in the same frequency band or different frequency bands of the transmission bus at the same time, and transmits the modulated data to burning terminals through designated frequency bands (Step 101). Each burning terminal can include a burner. In this case, the modulating process of CDMA technology is used to modulate the data carrying the bus signals of different designated types into data transmissive in the same frequency band of the transmission bus at the same time, and the modulating process of FDMA is used to modulate the data carrying the bus signals of different designated types into data transmissive in the different frequency bands of the transmission bus at the same time.

After receiving the data transmitted in the designated frequency bands, each of the burning terminals determines whether the received modulated data satisfy a characteristic modulating type of the burning terminal itself or not (Step 102 and Step 102′); if not, Step 102 and Step 102′ are continued, until the data satisfying the characteristic modulating type of the burning terminal itself are received; if yes, the received modulated data are demodulated into data that can be identified by the target chips of different bus types when the chips are burned (Step 103 and Step 103′), and then, the target chips of different bus types are burned (Step 104 and Step 104′), so as to burn the demodulated data to the target chips in parallel.

After the target chips are burned, the burning terminals perform characteristic modulation on the feedback signals of the target chips of different bus types (Step 105 and Step 105′), so as to modulate the feedback signals of the target chips into signals with specific identification information (e.g., chip identification codes) of the target chips, and return the modulated feedback signals of the target chips to the control terminal.

The control terminal demodulates the modulated feedback signals of the target chips of different bus types sent from the burning terminals into information that can be identified by the controller according to the specific identification information (e.g., the chip identification codes) of the target chips (Step 106); and then return to Step 100 to perform the subsequent burning process, so as to burn the target chips of different bus types in parallel.

The system and the method for parallel burning according to embodiments of the present invention can transmit the data to be burned carrying bus signals in different types on the same transmission bus line, so as to burn the chips of different bus types to be burned at the same time in parallel. As the transmission bus has a fixed bandwidth, which can be divided into different frequency bands, the data to be burned carrying bus signals in different types can be modulated into data that can be transmitted in the same frequency band or different transmission bands of the transmission bus through the modulating process using the CDMA or FDMA technology, so as to achieve the object of burning the chips of different bus types on the same transmission bus at the same time in parallel in the present invention. Then, the principle for dividing the bandwidth of the transmission bus of the present invention and the modulating process using the CDMA or FDMA technology will be illustrated below in detail.

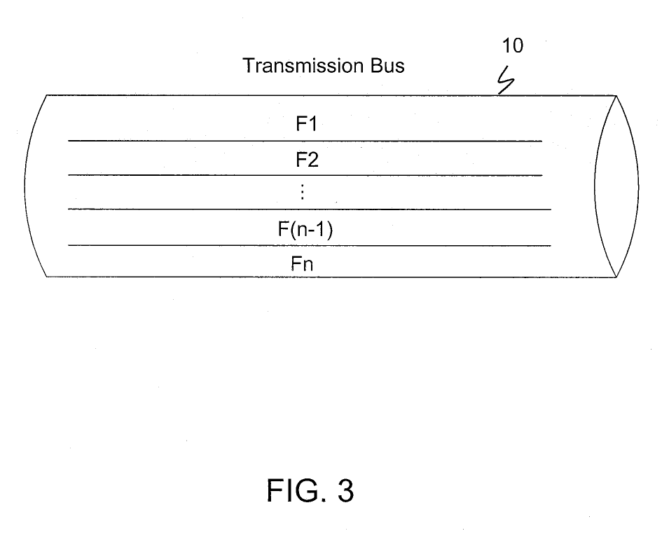

FIG. 3 is a schematic view of a transmission bus line with intrinsic bandwidth division according to the present invention. As shown in FIG. 3, when dividing the intrinsic bandwidth of the transmission bus line, the intrinsic bandwidth can be evenly divided into several frequency bands with the same frequency bandwidth, or can be divided into several frequency bands with different frequency bandwidths.

Then, an example is given below to illustrate how to evenly divide the intrinsic bandwidth into several frequency bands with the same frequency bandwidth.

Assuming the intrinsic bandwidth of the transmission bus line is X Mhz, which is evenly divided into n equal parts, at this time, F1 in FIG. 3 represents an area of frequency band 1 in the frequency range of 0˜X/n Mhz for transmitting data carrying a bus signal, and F2 represents an area of frequency band 2 for transmitting data carrying a bus signal. Similarly, F(n−1) represents an area of frequency band (n−1) for transmitting the data carrying a bus signal, and Fn represents an area of frequency band n for transmitting the data carrying a bus signal. For example, the frequency band F1 is set to transmit the modulated data carrying the bus signal of inter integrated circuit (IIC), and the frequency band F2 is set to transmit the modulated data carrying the bus signal of serial peripheral interface (SPI), and the frequency bands F(n−1), Fn, and other frequency bands are set to transmit the modulated data carrying the bus signal of in system programming (ISP) of other chip manufacturers. Therefore, the manufacturers. Therefore, the data carrying their individual bus signals can be transmitted in the corresponding frequency bands, without causing interferences to each other, so that the data carrying bus signals in different types are transmitted on the same transmission bus line in parallel through different frequency bands at the same time, or the data carrying bus signals in different types are transmitted at the same time through the same frequency band using different coding modes, and thus burning the chips of different bus types in parallel.

Moreover, in order to make full use of the intrinsic bandwidth of the transmission bus, and to prevent the waste of the intrinsic bandwidth, the following principles shall be followed in modulating the data carrying different bus signals into different frequency bands.

1. Bus type. The burning technical solution of the present invention is only applicable for the circumstance that the bus is a serial bus. For example, in a burning system, the commonly used serial program bus interfaces include IIC (for bidirectional data), SPI (for unidirectional transmission), joint test action group (JTAG, for unidirectional transmission), and some in-chip serial programming (ICSP) interfaces independently developed by certain manufacturers, such as priority interrupt control (PIC) single-chip microcomputer and power system on a chip (PSoC).

2. Bus transmission rate. Different bus frequencies are defined for different bus types. In order to balance the application of the bus, several signals with similar bus rates are assigned to the same frequency band for transmission. Bus signals with higher or lower bus rates can occupy one complete frequency band, which is often used when there are many bus types and the hardware resources are limited, for example, the transmission rate of the IIC bus is 400 Kbps, the transmission rate of the SPI bus is 1 Mbps, the transmission rate of the PIC and PSoC buses is almost 1 Mbps, and the transmission rate of the JTAG bus can be higher than 2 Mbps. Therefore, the data carrying bus signals of IIC and JTAG can be modulated for being transmitted on different frequency bands; and the data carrying the bus signals of SPI and PIC are modulated for transmission on another frequency band.

3. Circuit resources occupied by the buses. Different circuit resources are occupied by different bus types, so the data carrying bus signals occupying less circuit resources can be transmitted on a certain frequency band, or the data can be combined to be transmitted on several frequency bands.

4. Bus potentials. As different buses have different potentials, when the same frequency band is shared by the buses for transmitting signals, the bus signals having the same potential characteristics can be modulated to be transmitted in the same frequency band.

5. Bus utilization frequency. As for the bus types of the chips in actual burning process, the data to be burned that is small in amount and requires less burning time for the chips of a certain bus type on a target burning board can be modulated for being transmitted on a frequency band, so as to make full use of the frequency band support, to save the hardware cost, without influencing the whole normal burning of the system.

6. Data transmission direction. In order to simplify the process, the bidirectional data transmission can be changed into the unidirectional data transmission through expansion, i.e., the currently frequently used buses are all changed into the unidirectional data transmission, which saves the hardware resources, and the process is relatively simplified.

As described above, the data carrying bus signals in different types are transmitted on the same transmission bus line at the same time in different frequency bands, which is achieved through the modulating process of FDMA of modern multiplex technology. On the basis of the system and the method for parallel burning using the FDMA technology, the following data modulation and transmission mode can be further derived, so as to burn the chips of different bus types in parallel.

The data to be burned are modulated and then encoded in the Fn frequency band (which is any frequency band in the transmission bus), i.e., the modulating process using the CDMA of the current multiplex technology is used, so as to modulate the data carrying bus signals in different designated types into data that can be transmitted in the same designated frequency band (the Fn frequency band) of the transmission bus, which are then transmitted, demodulated, and burned. According to this process, the signals are transmitted through chips. Normally, each bit of information occupies several chips. Encoding signal=(Original Data) X (Chip Sequence), that is, the convolution of the original data with the chip sequence. All bus signals share the CDMA channel resource, and each bus has a unique code pattern, so as to be distinguished from other buses. Each bus combines its own code pattern with a long code chip, so as to recover the information transmitted to this bus, and to abandon the other information to other buses, and thus, the communication of different bus types is guaranteed, and the data carrying bus signals in different types can be encoded and transmitted in the same frequency band at the same time using different coding modes, so as to burn the chips of different bus types in parallel.

To sum up, the system and the method for parallel burning using multiplex technology of the present invention divide the intrinsic bandwidth of a transmission bus into different frequency bands, and modulate the data to be burned carrying bus signals in different types into data that can be transmitted in the same frequency band or different frequency bands of the same transmission bus at the same time through using the modulating process of CDMA or FDMA of the current multiplex technology. Therefore, the objective of the present invention to burn chips of different bus types in the same transmission bus at the same time in parallel is achieved. Moreover, under the condition of saving hardware resources, the chips of different types can be burned in parallel rapidly, so the burning time for the chips of different types is shortened, and the flexibility in burning the chips of different types is improved, which overcomes the disadvantages of the system and method for burning chips in the prior art in burning chips with different bus types that it is quite time consuming or wastes a lot of hardware resources.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A system for parallel burning using multiplex technology, for burning a plurality of chips of different bus types in the same transmission bus at the same time in parallel, the system comprising:
a main control unit, for dividing a bandwidth of the transmission bus into different frequency bands, for sending a control command, and for controlling data carrying bus signals of designated types to be transmitted in designated frequency bands of the transmission bus, wherein the control command includes a command for sending the data carrying the bus signals in the designated types;
a sending unit, for receiving the command for sending the data carrying the bus signals of the designated types from the main control unit, and transmitting the data carrying the bus signals of the designated types through the designated frequency bands;
a plurality of receiving units, for receiving the data from the sending unit to be output; and
a plurality of burners, for burning the data from the receiving units onto the chips of the designated bus types in parallel.

2. The system for parallel burning using multiplex technology as claimed in claim 1, wherein each of the receiving units is used to receive a feedback signal from the chip of the designated bus type and send the feedback signal to the sending unit; and wherein the sending unit is used to transmit the feedback signals to the main control unit.

3. The system for parallel burning using multiplex technology as claimed in claim 2, wherein each of the receiving units comprises:
a modulating unit, for modulating the feedback signal into a signal with a specific identification information of the chip; and
a demodulating unit, for demodulating the received data carrying the bus signals of the designated types into data identifiable while burning the chip.

4. The system for parallel burning using multiplex technology as claimed in claim 2, wherein the sending unit comprises:
a modulating unit, for modulating the data carrying the bus signals of the different designated types into data transmissive in the same frequency band or different frequency bands of the transmission bus simultaneously; and
a demodulating unit, for demodulating the feedback signals from the receiving units into information identifiable by the main control unit.

5. The system for parallel burning using multiplex technology as claimed in claim 4, wherein the modulating unit modulates the data carrying the bus signals of the different designated types into the data transmissive in the same designated frequency band of the transmission bus simultaneously utilizing a Code Division Multiple Access (CDMA) technology.

6. The system for parallel burning using multiplex technology as claimed in claim 4, wherein the modulating unit modulates the data carrying the bus signals of the different designated types into the data transmissive in the different designated frequency bands of the transmission bus simultaneously utilizing a Frequency Division Multiple Access (FDMA) technology.

7. The system for parallel burning using multiplex technology as claimed in claim 1, wherein the bus of the designated type is a serial bus.

8. A method for parallel burning using multiplex technology, for burning a plurality of chips of different bus types in the same transmission bus at the same time in parallel, the method comprising:
dividing a bandwidth of the transmission bus into different frequency bands;
sending a control command to control data carrying bus signals of designated types to be transmitted in designated frequency bands of the transmission bus by a control terminal; and
receiving the data transmitted in the designated frequency band, and burning the data onto the chips of the designated bus type in parallel by a plurality of burning terminals.

9. The method for parallel burning using multiplex technology as claimed in claim 8, further comprising:
receiving a feedback signal from each of the chips of the designated bus type by the burning terminals; and
transmitting each the feedback signal form each the burning terminal to the control end.

10. The method for parallel burning using multiplex technology as claimed in claim 9, further comprising:
modulating each the feedback signal into a signal having specific identification information of the chip by each the burning terminal; and
demodulating the received data transmitted in the designated frequency bands into data identifiable while burning the chips by each the burning terminal.

11. The method for parallel burning using multiplex technology as claimed in claim 9, further comprising:
modulating the data carrying the bus signals of the different designated types into data simultaneously transmissive in the same frequency band or different frequency bands of the frequency bands of the transmission bus by the control terminal; and
demodulating the feedback signal transmitted from the burning terminal into information identifiable for the control terminal by the control terminal.

12. The method for parallel burning using multiplex technology as claimed in claim 11, wherein the step of modulating the data carrying the bus signals of the different designated types into the data simultaneously transmissive in the same designated frequency band of the transmission bus is implemented utilizing a Code Division Multiple Access (CDMA) technology.

13. The method for parallel burning using multiplex technology as claimed in claim 11, wherein the step of modulating the data carrying the bus signal of the different designated type into the data simultaneously transmissive in the different designated frequency bands of the transmission bus is implemented utilizing a Frequency Division Multiple Access (FDMA) technology.

14. The method for parallel burning using multiplex technology as claimed in claim 8, wherein the bus of the designated type is a serial bus.
